(19) United States
(12) Patent Application Publication
(10) Pub. No.: US 2025/0126709 A1
(43) Pub. Date: Apr. 17, 2025

(54) PRINTED WIRING BOARD

(71) Applicant: IBIDEN CO., LTD., Ogaki (JP)

(72) Inventor: Tomoyuki IKEDA, Ogaki (JP)

(73) Assignee: IBIDEN CO., LTD., Ogaki (JP)

(21) Appl. No.: 18/915,900

(22) Filed: Oct. 15, 2024

(30) Foreign Application Priority Data
Oct. 16, 2023 (JP) 2023-177991

(51) Int. Cl. H05K 1/03; H05K 1/11; H05K 3/00; H05K 3/07; H05K 3/40

(52) U.S. Cl. CPC H05K 1/0373; H05K 1/116; H05K 3/0035; H05K 3/4069; H05K 3/07; H05K 2201/0209; H05K 2201/0388; H05K 2201/09509; H05K 2201/09554

(57) ABSTRACT

A printed wiring board includes an insulating layer, a conductor layer formed on the insulating layer, an adhesive layer formed on the conductor layer and including organic material, and a resin insulating layer formed on the insulating layer such that the resin insulating layer is covering the adhesive layer on the conductor layer formed on the insulating layer. The resin insulating layer includes resin and inorganic particles dispersed in the resin, and the adhesive layer has a smooth film part and a protruding part including protrusions protruding from the smooth film part such that a number of the inorganic particles in spaces between the protrusions with respect to a predetermined area is smaller than a number of the inorganic particles outside the spaces between the protrusions with respect to the predetermined area.

### CROSS-REFERENCE TO RELATED APPLICATIONS

The present application is based upon and claims the benefit of priority to Japanese Patent Application No. 2023-177991, filed Oct. 16, 2023, the entire contents of which are incorporated herein by reference.

### BACKGROUND OF THE INVENTION

### Field of the Invention

The present invention relates to a printed wiring board.

### Description of Background Art

Japanese Patent Application Laid-Open Publication No. 2001-203462 describes a method for manufacturing a multilayer printed wiring board. The entire contents of this publication are incorporated herein by reference.

### SUMMARY OF THE INVENTION

According to one aspect of the present invention, a printed wiring board includes an insulating layer, a conductor layer formed on the insulating layer, an adhesive layer formed on the conductor layer and including organic material, and a resin insulating layer formed on the insulating layer such that the resin insulating layer is covering the adhesive layer on the conductor layer formed on the insulating layer. The resin insulating layer includes resin and inorganic particles dispersed in the resin, and the adhesive layer has a smooth film part and a protruding part including protrusions protruding from the smooth film part such that a number of the inorganic particles in spaces between the protrusions with respect to a predetermined area is smaller than a number of the inorganic particles outside the spaces between the protrusions with respect to the predetermined area.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a printed wiring board according to an embodiment of the present invention;

FIG. 2 is an enlarged cross-sectional view schematically illustrating a part of a printed wiring board according to an embodiment of the present invention;

FIG. 3A is a cross-sectional view schematically illustrating a method for manufacturing a printed wiring board according to an embodiment of the present invention;

FIG. 3B is a cross-sectional view schematically illustrating a method for manufacturing according to an embodiment of the present invention;

FIG. 3C is a cross-sectional view schematically illustrating a method for manufacturing according to an embodiment of the present invention;

FIG. 3D is a cross-sectional view schematically illustrating a method for manufacturing according to an embodiment of the present invention; and

FIG. 3E is a cross-sectional view schematically illustrating a method for manufacturing according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### EMBODIMENT

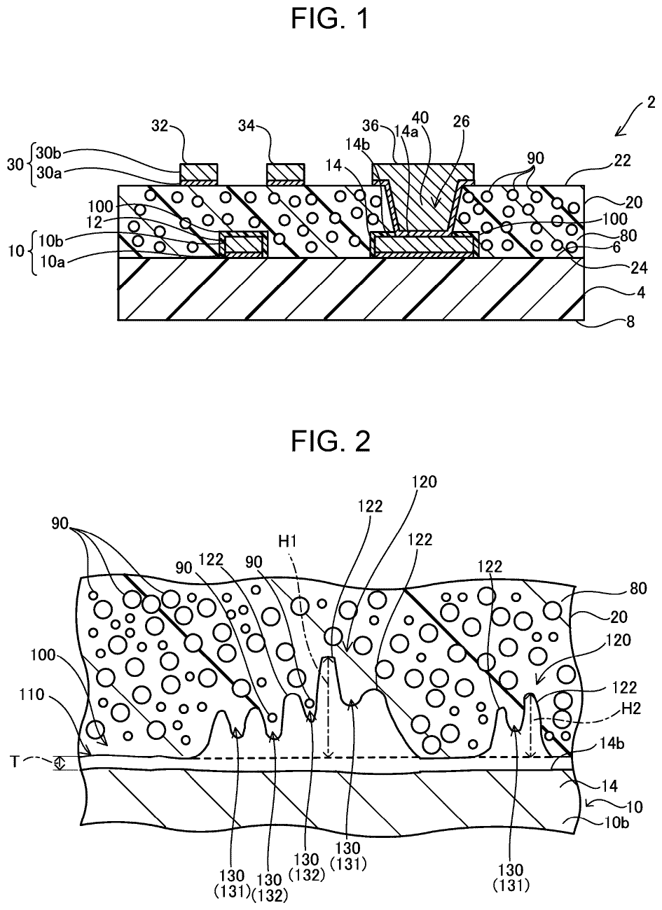

FIG. 1 is a cross-sectional view illustrating a printed wiring board 2 according to an embodiment of the present invention. As illustrated in FIG. 1, the printed wiring board 2 includes an insulating layer 4, a first conductor layer 10, a resin insulating layer 20, a second conductor layer 30, and a via conductor 40. The first conductor layer 10 is an example of a conductor layer. The via conductor 40 is formed in an opening 26 formed in the resin insulating layer 20. The printed wiring board 2 has an adhesive layer 100 on the first conductor layer 10. The adhesive layer 100 is sandwiched between the first conductor layer 10 and the resin insulating layer 20. The first conductor layer 10 and the second conductor layer 30 are adjacent to each other. There is no conductor layer between the first conductor layer 10 and the second conductor layer 30.

The insulating layer 4 is formed using a thermosetting resin. It is also possible that the insulating layer 4 is formed of a photocurable resin. The insulating layer 4 may contain inorganic particles such as silica particles. The insulating layer 4 may contain a reinforcing material such as a glass cloth. The insulating layer 4 has a third surface 6 and a fourth surface 8 on the opposite side with respect to the third surface 6.

The first conductor layer 10 is formed on the third surface 6 of the insulating layer 4. The first conductor layer 10 includes a signal wiring 12 and a pad 14. Although not illustrated in the drawings, the first conductor layer 10 also includes conductor circuits other than the signal wiring 12 and the pad 14. The first conductor layer 10 is mainly formed of copper. The first conductor layer 10 is formed of a seed layer (10a) on the insulating layer 4 and an electrolytic plating layer (10b) on the seed layer (10a). Surfaces (upper and side surfaces) of the first conductor layer 10 are smooth. Roughness of the surfaces of the first conductor layer 10 is expressed using a root mean square roughness (Rq). The root mean square roughness (Rq) of the surfaces of the first conductor layer 10 is 0.23 μm or less. The root mean square roughness (Rq) of the surfaces of the first conductor layer 10 is preferably 0.18 μm or less. The root mean square roughness (Rq) of the surfaces of the first conductor layer 10 is more preferably 0.1 μm or less.

A surface of the pad 14 is formed of a first surface (14a) and a second surface (14b). The first surface (14a) is exposed from the opening 26 formed in the resin insulating layer 20. The second surface (14b) is a surface other than the first surface (14a). The second surface (14b) has a root mean square roughness (Rq) of 0.23 μm or less. The first surface (14a) is not covered by the adhesive layer 100. The second surface (14b) is covered by the adhesive layer 100. Surfaces (upper and side surfaces) of the signal wiring 12 are covered by the adhesive layer 100. The side surface of the first conductor layer 10 is covered by the adhesive layer 100.

The adhesive layer 100 is formed of resin. The adhesive layer 100 is formed of an organic material (organic resin). The adhesive layer 100 does not contain inorganic particles. Or, the adhesive layer 100 contains inorganic particles such as silica particles. When the adhesive layer 100 contains inorganic particles, the inorganic particles each have a diameter of several nm. The organic material is a nitrogen-based organic compound. The nitrogen-based organic compound is, for example, a tetrazole compound. Examples of the nitrogen-based organic compound are described in Japanese Patent Application Laid-Open Publication No. 2015-54987. The entire contents of this publication are incorporated herein by reference. The adhesive layer 100 does not cover the third surface 6 exposed from the first conductor layer 10. The adhesive layer 100 is sandwiched between the first conductor layer 10 and the resin insulating layer 20. The adhesive layer 100 adheres the first conductor layer 10 and the resin insulating layer 20.

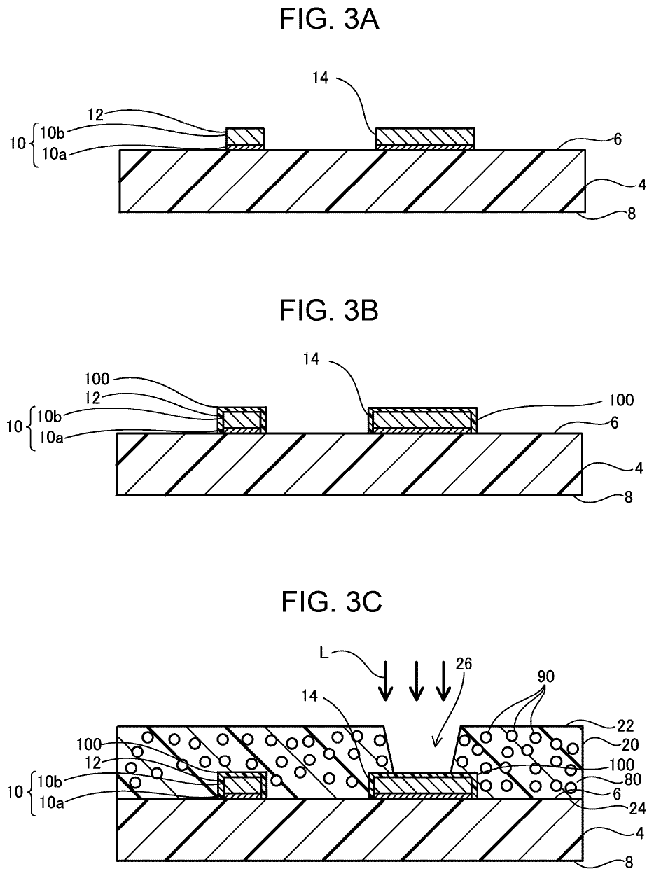

FIG. 2 is an enlarged cross-sectional view illustrating a part of the adhesive layer 100 formed on the second surface (14b) of the pad 14. As illustrated in FIG. 2, the adhesive layer 100 is formed of a smooth film 110, which is substantially smooth, and multiple protruding parts 120 protruding from the smooth film 110. The adhesive layer 100 formed on a side surface of the pad 14 is formed of a smooth film 110 and multiple protruding parts 120 similar to the adhesive layer 100 illustrated in FIG. 2, and also has a similar shape. The adhesive layer 100 formed on an upper surface and a side surface of the signal wiring 12 is formed of a smooth film 110 and multiple protruding parts 120 similar to that illustrated in FIG. 2, and also has a similar shape.

The smooth film 110 has a substantially uniform thickness (T). The thickness (T) of the smooth film 110 is 10 nm or more and 120 nm or less. A ratio (S1/S2) of an area (S1) of the smooth film 110 exposed from the protruding parts 120 to an area (S2) of the adhesive layer 100 is 0.1 or more and 0.5 or less. The smooth film 110 on the upper surface of the first conductor layer 10 is formed substantially along a shape of the upper surface of the first conductor layer 10. The smooth film 110 on the second surface (14b) of the first conductor layer 10 is formed substantially along a shape of the second surface (14b) of the first conductor layer 10. The smooth film 110 on the side surface of the first conductor layer 10 is formed substantially along a shape of the side surface of the first conductor layer 10. When undulations are formed on the upper surface and the side surface of the first conductor layer 10, the smooth film 110 follows the undulations.

The protruding parts 120 are formed of multiple protrusions 122. Due to the multiple protrusions 122, unevenness is formed on upper surfaces of the protruding parts 120. The number of the protrusions 122 per 1 mm² is 5 or more and 15 or less. The protruding parts 120 have heights (H1, H2) between the upper surface of the smooth film 110 and top parts of the protruding parts 120. A maximum value of the heights (H1, H2) is 10 times or more and 30 times or less the thickness (T) of the smooth film 110. The heights (H1, H2) are 200 nm or more and 450 nm or less.

The resin insulating layer 20 is formed on the first conductor layer 10 via the adhesive layer 100. The resin insulating layer 20 is adhered to the first conductor layer 10 by the adhesive layer 100. The resin insulating layer 20 has a first surface 22 and a second surface 24 on the opposite side with respect to the first surface 22. The second surface 24 of the resin insulating layer 20 faces the first conductor layer 10. The second surface 24 is in contact with the adhesive layer 100. The resin insulating layer 20 has the opening 26 that exposes the pad 14. The first surface 22 of the resin insulating layer 20 has no unevenness. The first surface 22 is not roughened. The first surface 22 is formed smooth. A thickness of the resin insulating layer 20 is two or more times a thickness of the second conductor layer 30. The thickness of the resin insulating layer 20 is a distance between the first surface 22 and the upper surface of the first conductor layer 10.

The resin insulating layer 20 contains a resin 80 and a large number of inorganic particles 90 dispersed in the resin 80. The resin insulating layer 20 is formed of the resin 80 and the large number of inorganic particles 90 dispersed in the resin 80. The resin 80 is an epoxy resin. Examples of the resin include a thermosetting resin and a photocurable resin. Examples of the inorganic particles 90 include silica particles and alumina particles. An amount of the inorganic particles 90 in the resin insulating layer 20 is 70 wt % or more.

As illustrated in FIG. 2, spaces 130 exist between the multiple protrusions 122 that form the protruding parts 120 of the adhesive layer 100. There are multiple spaces 130. The spaces 130 are filled with the resin insulating layer 20. The resin insulating layer 20 in the spaces 130 contains the resin 80 derived from the resin insulating layer 20. The resin insulating layer 20 in the spaces 130 may or may not contain the inorganic particles 90 derived from the resin insulating layer 20. The number (B1) of inorganic particles 90 in the spaces 130 per given area is smaller than the number (B2) of inorganic particles 90 per given area outside the spaces 130. A ratio ((the number (B1))/(the number (B2))) of the number (B1) to the number (B2) is less than 0.5. The ratio ((the number (B1))/(the number (B2))) may be less than 0.1. The ratio ((the number (B1))/(the number (B2))) may be 0. When the ratio is 0, the ratio ((the number (B1))/(the number (B2))) may be expressed as Ratio 0. The resin insulating layer 20 in the spaces 130 corresponding to Ratio 0 does not contain inorganic particles 90 in the spaces 130. The number (B1) and the number (B2) are measured using a cross section of the printed wiring board 2. The cross section used for the measurement is obtained by cutting the printed wiring board 2 with a plane perpendicular to the first surface 22. An example of the given area is 4 μm² or more and 25 μm² or less. Preferably, multiple measurement locations are used for the measurement. The measurement locations are different from each other. For example, the number of measurement locations is 5 or more and 30 or less. The number (B1) and the number (B2) are each an average number of inorganic particles 90 at the measurement locations.

When the resin insulating layer 20 in the multiple spaces 130 is observed, the spaces 130 are classified into first spaces 131 and second spaces 132. The first space 131 is filled with only the resin 80. The second spaces 132 are filled with the inorganic particles 90 and the resin 80. A ratio (N1/N2) of the number (N1) of the first spaces 131 to the total number (N2) of the spaces 130 is 0.5 or more. More than half of the spaces 130 do not contain inorganic particles 90. The ratio (N1/N2) is preferably 0.7 or more. The ratio (N1/N2) is more preferably 0.85 or more. It is also possible that the ratio (N1/N2) is 1. The total number (N2) of the spaces 130 used for calculating the ratio (N1/N2) is preferably 10 or more. The total number (N2) is a sum of the number of the first spaces 131 and the number of the second spaces 132. The total number (N2) may be represented by the number of measurement locations. For example, when ten spaces 130 are evaluated regarding the presence or absence of inorganic particles, the total number (N2) is ten.

As illustrated in FIG. 1, the second conductor layer 30 is formed on the first surface 22 of the resin insulating layer 20. The second conductor layer 30 includes a first signal wiring 32, a second signal wiring 34, and a land 36. Although not illustrated in the drawings, the second conductor layer 30 also includes conductor circuits other than the first signal wiring 32, the second signal wiring 34, and the land 36. The first signal wiring 32 and the second signal wiring 34 form a pair wiring. The second conductor layer 30 is mainly formed of copper. The second conductor layer 30 is formed of a seed layer (30a) on the first surface 22 and an electrolytic plating layer (30b) on the seed layer (30a).

The via conductor 40 is formed in the opening 26. The via conductor 40 connects the first conductor layer 10 and the second conductor layer 30. In FIG. 1, the via conductor 40 connects the pad 14 and the land 36. The via conductor 40 is formed of a seed layer (30a) and an electrolytic plating layer (30b) on the seed layer (30a).

A length of each side of the printed wiring board 2 of the embodiment is 50 mm or more. The length of each side is preferably 100 mm or more. The length of each side is 250 mm or less.

### Method for Manufacturing Printed Wiring Board

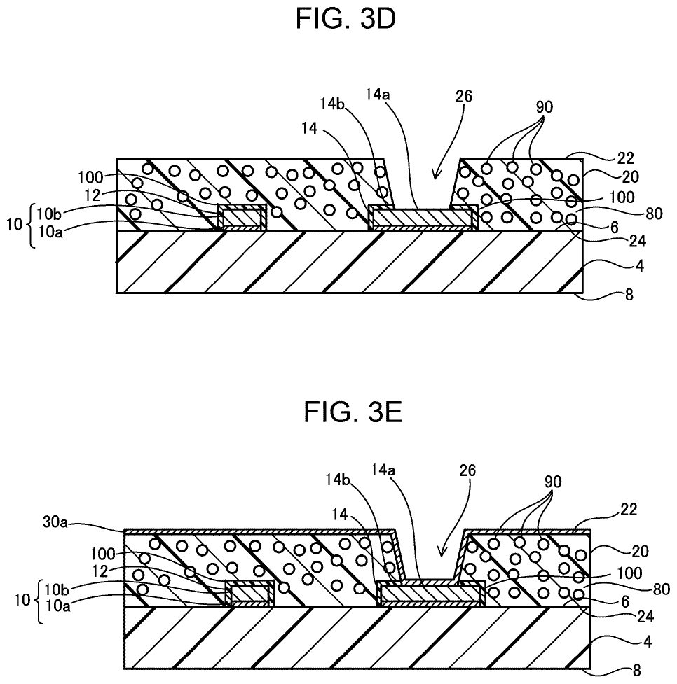

FIGS. 3A-3E illustrate a method for manufacturing a printed wiring board 2 according to an embodiment of the present invention. FIGS. 3A-3E are cross-sectional views. FIG. 3A illustrates the insulating layer 4 and the first conductor layer 10 formed on the third surface 6 of the insulating layer 4. The first conductor layer 10 is formed using a semi-additive method.

As illustrated in FIG. 3B, the adhesive layer 100 is formed on the upper surface and the side surface of the first conductor layer 10. For example, the adhesive layer 100 is formed by immersing the intermediate substrate illustrated in FIG. 3A in a chemical solution containing a nitrogen-based organic compound. The chemical solution has a pH or 7 or less. By immersing the intermediate substrate in the chemical solution, the adhesive layer 100 including the smoothing film 110 and the protruding parts 120 is formed on the upper and side surfaces of the first conductor layer 10. Before the intermediate substrate is immersed in the chemical solution, an oxide film on the upper and side surfaces of the first conductor layer 10 is removed. In a modified example, the adhesive layer 100 is formed by applying a chemical solution on the first conductor layer 10. When the adhesive layer 100 is formed, the intermediate substrate is taken out from the chemical solution. The adhesive layer 100 is dried. The upper surface of the adhesive layer 100 before the drying may be smooth. In this case, by the drying, a part of the adhesive layer 100 aggregates. By the aggregating, the adhesive layer 100 including the smooth film 110 and the protruding parts 120 is formed.

The resin insulating layer 20 is formed on the first conductor layer 10 which is covered by the adhesive layer 100. The second surface 24 of the resin insulating layer 20 faces the third surface 6 of the insulating layer 4. The second surface 24 is in contact with the adhesive layer 100. The spaces 130 exist between adjacent protrusions 122. The spaces 130 between the multiple protrusions 122 are filled with the resin insulating layer 20. The spaces 130 are filled with the resin insulating layer 20. Sizes of the spaces 130 are small. The spaces 130 vary in size. Complex unevennesses are formed by the protrusions 122. Therefore, the spaces 132 that are filled with the resin insulating layer 20 containing inorganic particles 90 and the spaces 131 that are filled with the resin insulating layer 20 not containing inorganic particles 90 coexist. Or, all the spaces are filled with the resin insulating layer 20 not containing inorganic particles 90.

As illustrated in FIG. 3C, laser (L) is irradiated from above the resin insulating layer 20. The laser (L) penetrates the resin insulating layer 20. The laser (L) penetrates the adhesive layer 100 covering the pad 14 and reaches the pad 14. Or, the adhesive layer 100 is not completely removed by the laser (L). A bottom of the opening 26 is formed by the adhesive layer 100. The opening 26 for a via conductor reaching the pad 14 is formed. Or, the opening 26 for a via conductor reaching the adhesive layer 100 is formed. The adhesive layer 100 covering the pad 14 is exposed by the opening 26. The laser (L) is, for example, UV laser or CO₂ laser. In the example of FIG. 3C, the bottom of the opening 26 is formed by the adhesive layer 100.

As illustrated in FIG. 3D, the inside of the opening 26 is cleaned. When the adhesive layer 100 is not completely removed by the laser (L), the adhesive layer 100 exposed from the opening 26 is removed by cleaning the inside of the opening 26. The first surface (14a) of the pad 14 is exposed from the opening 26. Resin residues generated when the opening 26 is formed are removed. The cleaning of the inside of the opening 26 is performed using plasma. That is, the cleaning is performed by a dry process. In the embodiment, the cleaning can be performed using a chemical solution containing an oxidizing agent. An example of the oxidizing agent is potassium permanganate. The cleaning includes a desmear treatment. The adhesive layer 100 formed between the second surface 24 of the resin insulating layer 20 and the pad 14 is not removed. Therefore, no gap is formed between the second surface 24 of the resin insulating layer 20 and the pad 14.

As illustrated in FIG. 3E, the seed layer (30a) is formed on the first surface 22 of the resin insulating layer 20. The seed layer (30a) is formed by electroless plating. It is also possible that the seed layer (30a) is formed by sputtering.

A plating resist is formed on the seed layer (30a). The plating resist has openings for forming the first signal wiring 32, the second signal wiring 34, and the land 36.

The electrolytic plating layer (30b) is formed on the seed layer (30a) exposed from the plating resist. The electrolytic plating layer (30b) is formed of copper. The electrolytic plating layer (30b) fills the opening 26. The first signal wiring 32, the second signal wiring 34, and the land 36 are formed by the seed layer (30a) and the electrolytic plating film (30b) on the first surface 22. The second conductor layer 30 is formed. The via conductor 40 is formed by the seed layer (30a) and the electrolytic plating film (30b) in the opening 26. The via conductor 40 connects the pad 14 and the land 36. The first signal wiring 32 and the second signal wiring 34 form a pair wiring.

The plating resist is removed. The seed layer (30a) exposed from the electrolytic plating layer (30b) is removed. The second conductor layer 30 and the via conductor 40 are formed at the same time. The printed wiring board 2 of the embodiment is obtained.

The printed wiring board 2 of an embodiment has the adhesive layer 100 sandwiched between the first conductor layer 10 and the resin insulating layer 20. The adhesive layer 100 adheres the first conductor layer 10 and the resin insulating layer 20. The adhesive layer 100 is formed of the smooth film 110, which is substantially smooth, and the protruding parts 120 protruding from the smooth film 110. The adhesive layer 100 has unevenness formed by the protruding parts 120 and the smooth film 110. The protruding parts 120 have unevenness formed by the multiple protrusions 122. Therefore, the first conductor layer 10 and the resin insulating layer 20 are sufficiently adhered to each other via the adhesive layer 100. For example, even when each side of the printed wiring board 2 has a length of 50 mm or more, the resin insulating layer 20 is unlikely to peel off from the first conductor layer 10. Even when each side of the printed wiring board 2 has a length of 100 mm or more, a crack caused the adhesive layer 100 is unlikely to occur in the resin insulating layer 20.

The coefficient of thermal expansion (CTE) of the adhesive layer 100 and the CTE of the resin insulating layer 20 are different. For example, the amount of inorganic particles contained therein is different between the two. Or, the resin insulating layer 20 contains the inorganic particles 90, and the adhesive layer 100 does not contain inorganic particles. Or, the CTE of the resin forming the adhesive layer 100 and the CTE of the resin forming the resin insulating layer 20 are different. When the printed wiring board 2 is subjected to a thermal impact, the amount of deformation of the adhesive layer 100 and the amount of deformation of the resin insulating layer 20 are different. Or, the deformation amount of the resin insulating layer 20 filling the spaces 130 and the amount of deformation of the adhesive layer 100 are different. In particular, when the resin insulating layer 20 filling the spaces 130 contains the inorganic particles 90, the difference in the amount of deformation between the two is large. When the difference in the amount of deformation between the two is large, the protrusions 122 are likely to be damaged. In the printed wiring board 2 of the embodiment, the number (B1) of the inorganic particles 90 in the spaces 130 per given area is smaller than the number (B2) of the inorganic particles 90 outside the spaces 130 per given area. The difference in the amount of deformation between the resin insulating layer 20 filling the spaces 130 and the adhesive layer 100 is small. Or, the CTE of the adhesive layer 100 is greater than the CTE of the resin insulating layer 20 filling the spaces 130, and the CTE of the resin insulating layer 20 filling the spaces 130 is greater than the CTE of the resin insulating layer 20 outside the spaces. These CTEs gradually increase. These CTEs gradually change. Therefore, the protrusions 122 are unlikely to be damaged. The resin insulating layer 20 is unlikely to peel off from the first conductor layer 10. A high quality printed wiring board 2 is provided.

In the printed wiring board 2 of the embodiment, the root mean square roughness (Rq) of the surfaces (upper and side surfaces) of the first conductor layer 10 is 0.23 μm or less. Therefore, when data is transmitted via the conductor circuit included in the first conductor layer 10, transmission loss is small. When a high-speed signal is transmitted, noise is unlikely to occur. The printed wiring board 2 of the embodiment can transmit high-speed signals with low loss and can suppress peeling between the conductor layer and the resin insulating layer. A high quality printed wiring board 2 is provided.

### First Alternative Example

A printed wiring board 2 of a first alternative example of the embodiment includes multiple conductor layers, multiple interlayer resin insulating layers, and multiple via conductors. The conductor layers and the interlayer resin insulating layers are alternately laminated. Adjacent conductor layers are connected by the via conductors. In the first alternative example, the number of the conductor layers is 5 or more and 20 or less. The interlayer resin insulating layers have substantially equal thicknesses. In the printed wiring board 2, the conductor layers and the interlayer resin insulating layers can be adhered to each other with adhesive layers 100. In the embodiment and the first alternative example, the adhesive layers 100 have the same structure and shape. Similar to the embodiment, the adhesive layers 100 are formed on upper and side surfaces of the conductor layers. The adhesive layers 100 are each sandwiched between a conductor layer and an interlayer resin insulating layer. Even when the number of the conductor layers is 5 or more, the interlayer resin insulating layers are unlikely to peel off from the conductor layers. Since the number of the conductor layers is 20 or less, a crack caused by the adhesive layers 100 is unlikely to occur in the interlayer resin insulating layers. The number of the conductor layers is preferably 10 or more. The number of the conductor layers is more preferably 15 or more. The adhesive layers 100 effectively function.

The printed wiring board 2 of FIG. 1 includes two conductor layers (the first conductor layer 10 and the second conductor layer 30). There is one first conductor layer 10. There is one second conductor layer 30. The first conductor layer 10 and the second conductor layer 30 are included in the conductor layers of the first alternative example. The resin insulating layer 20 of FIG. 1 is included in the interlayer resin insulating layers of the first alternative example. In the first alternative example, the conductor layers other than the first conductor layer 10 and the second conductor layer 30 are third conductor layers. In the first alternative example, one of the multiple interlayer resin insulating layers is formed directly on the resin insulating layer 20 and the second conductor layer 30. The interlayer resin insulating layer formed directly on the resin insulating layer 20 and the second conductor layer 30 is a first interlayer resin insulating layer. In the first alternative example, an adhesive layer 100 is formed between the first interlayer resin insulating layer and the second conductor layer 30. Or, no adhesive layer 100 is formed between the first interlayer resin insulating layer and the second conductor layer 30. The conductor layers of first alternative example and the first conductor layer 10 of the embodiment are similar. The two have similar root mean square roughness (Rq).

### Second Alternative Example

In a second alternative example, a conductor layer is formed below the insulating layer 4 of the printed wiring board 2 of FIG. 1. And, the insulating layer 4 is formed by the resin insulating layer 20 of FIG. 1. The conductor layer and the first conductor layer 10 are connected by a via conductor penetrating the resin insulating layer sandwiched between the conductor layer and the first conductor layer 10. Except for forming the conductor layer below the insulating layer 4, forming the insulating layer 4 by the resin insulating layer 20, and forming the via conductor in the resin insulating layer sandwiched between the conductor layer and the first conductor layer 10, the embodiment and the second alternative example are the same. The conductor layers of second alternative example and the first conductor layer 10 of the embodiment are similar. The two have similar root mean square roughness (Rq).

Japanese Patent Application Laid-Open Publication No. 2001-203462 describes a method for manufacturing a multilayer printed wiring board. The method includes sequentially laminating a conductor circuit and an interlayer resin insulating layer on a substrate; and forming a layer containing a triazine compound on at least a part of a surface of the conductor circuit. The conductor circuit and the interlayer resin insulating layer are adhered to each other via a layer containing a triazine compound.

In a printed wiring board manufactured using the technology of Japanese Patent Application Laid-Open Publication No. 2001-203462, when a large stress acts between the conductor circuit and the interlayer resin insulating layer, peeling is expected to occur between the conductor circuit and the interlayer resin insulating layer. For example, when the number of conductor layers in a build-up layer is 5 or more, it is considered that a stress acting between the conductor circuit and the interlayer resin insulating layer increases. When the number of conductor layers in a build-up layer is 5 or more, peeling is expected to occur between the conductor circuit and the interlayer resin insulating layer. For example, when a length of each side of the printed wiring board exceeds 50 mm, peeling is expected to occur between the conductor circuit and the interlayer resin insulating layer.

A printed wiring board according to an embodiment of the present invention includes an insulating layer; a conductor layer that is formed on the insulating layer; an adhesive layer that is formed on the conductor layer and is formed of an organic material; and a resin insulating layer that is formed on the insulating layer and the conductor layer. The resin insulating layer contains a resin and inorganic particles dispersed in the resin. A surface of the conductor layer is substantially smooth. The adhesive layer is formed of a smooth film and a protruding part protruding from the smooth film. The protruding part is formed of multiple protrusions. Spaces between the multiple protrusions are filled with the resin insulating layer. A number (B1) of the inorganic particles in the spaces per given area is smaller than a number (B2) of the inorganic particles outside the spaces per given area.

A printed wiring board according to an embodiment of the present invention has the adhesive layer sandwiched between the conductor layer and the resin insulating layer. The adhesive layer adheres the conductor layer and the resin insulating layer. The adhesive layer is formed of the smooth film, which is substantially smooth, and the protruding part protruding from the smooth film. The adhesive layer has unevenness formed by the protruding part and the smooth film. The protruding part has unevenness formed by the multiple protrusions. Therefore, the conductor layer and the resin insulating layer are sufficiently adhered to each other via the adhesive layer. The coefficient of thermal expansion (CTE) of the adhesive layer and the CTE of the resin insulating layer are different. When the printed wiring board is subjected to a thermal impact, the amount of deformation of the resin insulating layer filling the spaces between the protrusions of the adhesive layer and the amount of deformation of the adhesive layer are different. In particular, when the resin insulating layer filling the spaces contains inorganic particles, the difference in the amount of deformation between the two is large. When the difference in the amount of deformation between the two is large, the protrusions are likely to be damaged. In the printed wiring board of the embodiment, the number (B1) of the inorganic particles in the spaces per given area is smaller than the number (B2) of the inorganic particles outside the spaces per given area. The difference in the amount of deformation between the resin insulating layer filling the spaces and the adhesive layer is small. The protrusions are unlikely to be damaged. The resin insulating layer is unlikely to peel off from the conductor layer. A high quality printed wiring board is provided.

Obviously, numerous modifications and variations of the present invention are possible in light of the above teachings. It is therefore to be understood that within the scope of the appended claims, the invention may be practiced otherwise than as specifically described herein.

1. A printed wiring board, comprising:
an insulating layer;
a conductor layer formed on the insulating layer;
an adhesive layer formed on the conductor layer and comprising organic material; and
a resin insulating layer formed on the insulating layer such that the resin insulating layer is covering the adhesive layer on the conductor layer formed on the insulating layer,
wherein the resin insulating layer includes resin and inorganic particles dispersed in the resin, and the adhesive layer has a smooth film part and a protruding part comprising protrusions protruding from the smooth film part such that a number of the inorganic particles in spaces between the protrusions with respect to a predetermined area is smaller than a number of the inorganic particles outside the spaces between the protrusions with respect to the predetermined area.

2. The printed wiring board according to claim 1, wherein the conductor layer has a smooth surface having a root mean square roughness Rq of 0.23 μm or less.

3. The printed wiring board according to claim 1, wherein the adhesive layer is formed such that a ratio of the number of the inorganic particles in the spaces between the protrusions with respect to the predetermined area to the number of the inorganic particles outside the spaces between the protrusions with respect to the predetermined area is smaller than 0.5.

4. The printed wiring board according to claim 3, wherein the ratio of the number of the inorganic particles in the spaces between the protrusions with respect to the predetermined area to the number of the inorganic particles outside the spaces between the protrusions with respect to the predetermined area is 0.

5. The printed wiring board according to claim 1, wherein the number of the spaces between the protrusions is 2 or more, the spaces include first spaces filled with only the resin and second spaces filled with the inorganic particles and the resin such that a ratio of a number of the first spaces to a total number of the spaces is 0.5 or more.

6. The printed wiring board according to claim 5, wherein the ratio of the number of the first spaces to the total number of the spaces is 1.

7. The printed wiring board according to claim 1, wherein the adhesive layer is formed such that the smooth film part has a uniform thickness and that a maximum value of a height of the protruding part between an upper surface of the smooth film part and a top part of the protruding part is in a range of 10 to 30 times the uniform thickness of the smooth film part.

8. The printed wiring board according to claim 1, wherein the adhesive layer is formed such that the smooth film part has a uniform thickness in a range of 10 nm to 120 nm and that a height of the protruding part between an upper surface of the smooth film part and a top part of the protruding part is in a range of 200 nm to 450 nm.

9. The printed wiring board according to claim 1, wherein the adhesive layer is formed such that a ratio of an area of the smooth film part exposed from the protruding part to an area of the adhesive layer is in a range of 0.1 to 0.5.

10. The printed wiring board according to claim 1, wherein the adhesive layer is formed such that the adhesive layer is not covering the insulating layer exposed from the conductor layer.

11. The printed wiring board according to claim 1, wherein the adhesive layer is formed such that a number of the protrusions per 1 mm² is in a range of 5 to 15.

12. The printed wiring board according to claim 2, wherein the adhesive layer is formed such that a ratio of the number of the inorganic particles in the spaces between the protrusions with respect to the predetermined area to the number of the inorganic particles outside the spaces between the protrusions with respect to the predetermined area is smaller than 0.5.

13. The printed wiring board according to claim 12, wherein the ratio of the number of the inorganic particles in the spaces between the protrusions with respect to the predetermined area to the number of the inorganic particles outside the spaces between the protrusions with respect to the predetermined area is 0.

14. The printed wiring board according to claim 2, wherein the number of the spaces between the protrusions is 2 or more, the spaces include first spaces filled with only the resin and second spaces filled with the inorganic particles and the resin such that a ratio of a number of the first spaces to a total number of the spaces is 0.5 or more.

15. The printed wiring board according to claim 14, wherein the ratio of the number of the first spaces to the total number of the spaces is 1.

16. The printed wiring board according to claim 2, wherein the adhesive layer is formed such that the smooth film part has a uniform thickness and that a maximum value of a height of the protruding part between an upper surface of the smooth film part and a top part of the protruding part is in a range of 10 to 30 times the uniform thickness of the smooth film part.

17. The printed wiring board according to claim 2, wherein the adhesive layer is formed such that the smooth film part has a uniform thickness in a range of 10 nm to 120 nm and that a height of the protruding part between an upper surface of the smooth film part and a top part of the protruding part is in a range of 200 nm to 450 nm.

18. The printed wiring board according to claim 2, wherein the adhesive layer is formed such that a ratio of an area of the smooth film part exposed from the protruding part to an area of the adhesive layer is in a range of 0.1 to 0.5.

19. The printed wiring board according to claim 2, wherein the adhesive layer is formed such that the adhesive layer is not covering the insulating layer exposed from the conductor layer.

20. The printed wiring board according to claim 2, wherein the adhesive layer is formed such that a number of the protrusions per 1 mm² is in a range of 5 to 15.
